(19) United States
(12) Patent Application Publication
(10) Pub. No.: US 2020/0137909 A1
(43) Pub. Date: Apr. 30, 2020

(54) METHOD OF PREVENTING NECK DISCOMFORT FOR USERS OF ELECTRONIC DEVICES

(71) Applicant: Michael Joseph Field, Indianapolis, IN (US)

(72) Inventor: Michael Joseph Field, Indianapolis, IN (US)

(21) Appl. No.: 16/173,229

(22) Filed: Oct. 29, 2018

(51) Int. Cl. H05K 5/02; F16M 11/32

(52) U.S. Cl. CPC H05K 5/0234; F16M 13/02; F16M 11/32

(57) ABSTRACT

A method of ergonomically preventing tech neck for users of an electronic device is provided. The method embodied in an electronic device case providing telescoping legs to support the attached electronic device in innumerable positions and orientations. The telescopic legs are pivotably connected to recesses along a rear portion of the case so that the former may fold into the recesses in a flush condition when not in use. The distal ends of the telescopic legs may provide foldable feet to further stabilize the systemic cases in the many positions and orientation the encased electronic devices are secured in.

### BACKGROUND OF THE INVENTION

The present invention relates to electronic device cases and, more particularly, to a method of ergonomically preventing tech neck for users of an electronic device, the method embodied in an electronic device case providing telescoping legs to support the attached electronic device in innumerable positions and orientations.

Current portable electronic device cases are typically adapted to merely be placed and positions on a flat surface with the screen facing upwardly. As a result, many users of such encased electronic devices spend too much time holding their head flexed and forward while looking down at their handheld device and/or laptop screen, which places their cervical spine in a tenuous position, causing a painful condition known colloquially as “tech neck”.

Furthermore, current electronic device cases are typically flat, rectangular objects that can be difficult to place in an appropriate position for hands-free viewing. In other words, such cases limit the height and number of positions available to securely display the electronic device.

As can be seen, there is a need for a method of ergonomically preventing tech neck for users of an electronic device through a case adapted to safely and securely view and interact with the encased electronic device.

The systemic case embodied by the present invention provides stable positions to view and interact with the associated electronic device through a plurality of telescoping 360-degree swivel legs enabling movement of the case among various elevations and an infinite number of positions. The legs may provide a plurality of detachable, pivotable feet to selectively support the case and associated electronic device in the above-mentioned elevations and positions. The legs are also foldable into the systemic case so the latter may even provide the flat configuration of traditional electronic device cases.

### SUMMARY OF THE INVENTION

In one aspect of the present invention, a method of ergonomically preventing tech neck for users of an electronic device includes the steps of: providing a systemic case dimensioned to secure a rear portion of the electronic device; the systemic case having a rear portion with a plurality of elongated recess there along; a first pivotable connection provided in one end of each elongated recess; and a telescopic leg pivotable connected to each first pivotable connection so as to be movable between a flush condition circumscribed by the respective elongated recess and an operable condition so that a distal end of the telescopic leg may engage a supporting surface; encasing the electronic device in the systemic case; and moving two or more telescopic legs in the operable condition so that the systemic case is elevated above said supporting surface, and then moving an additional two telescopic legs to the operable condition, further changing the orientation of the systemic case in a four-legged orientation; and then selectively changing the elevation of the systemic case relative to the supporting surface to prevent tech neck; and then finally moving the two telescopic legs and the additional two telescopic legs to the flush condition for storage.

These and other features, aspects and advantages of the present invention will become better understood with reference to the following drawings, description and claims.

### BRIEF DESCRIPTION OF THE DRAWINGS

FIG. 1 is a perspective view of an exemplary embodiment of the present invention;

FIG. 2 is an exploded perspective view of an exemplary embodiment of the present invention;

FIG. 3 is a bottom plan view of an exemplary embodiment of the present invention;

FIG. 4 is a bottom plan view of an exemplary embodiment of the present invention, demonstrating relative motion and operation of telescopic legs about the first pivotable connection; and

FIG. 5 is a detail elevation view of an exemplary embodiment of the present invention, indicated by line 5-5 of FIG. 4, demonstrating relative motion and operation of the feet of the telescopic legs about the second pivotable connection;

FIG. 6 is an exploded perspective view of an exemplary embodiment of the present invention; and

FIG. 7 is a detail exploded view of an alternative embodiment of FIG. 5 of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides a method of ergonomically preventing tech neck for users of an electronic device, the method embodied in an electronic device case providing telescoping legs to support the attached electronic device in innumerable positions and orientations. The telescopic legs are pivotably connected to recesses along a rear portion of the case so that the former may fold into the recesses in a flush condition when not in use. The distal ends of the telescopic legs may provide foldable feet to further stabilize the systemic cases in the many positions and orientation the encased electronic devices are secured in.

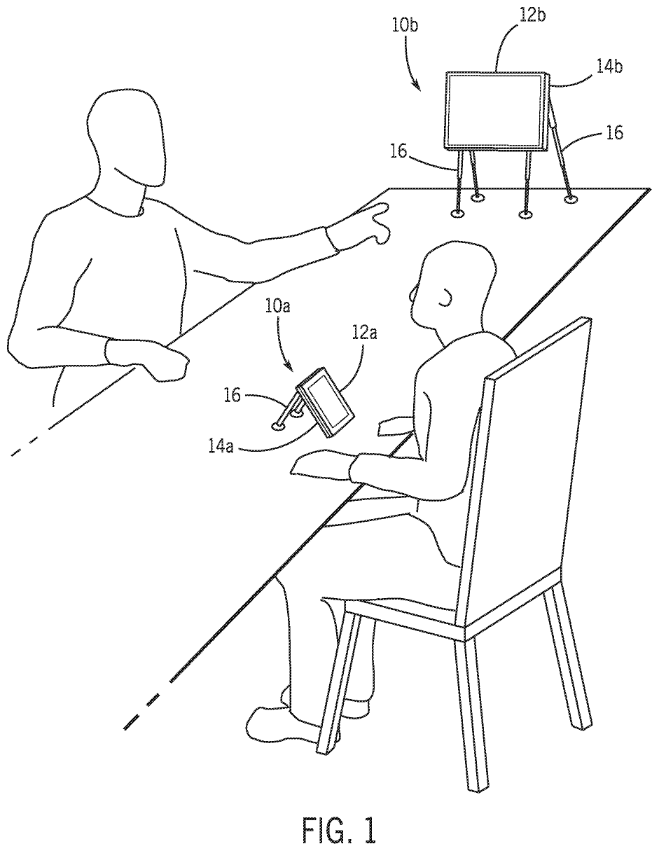

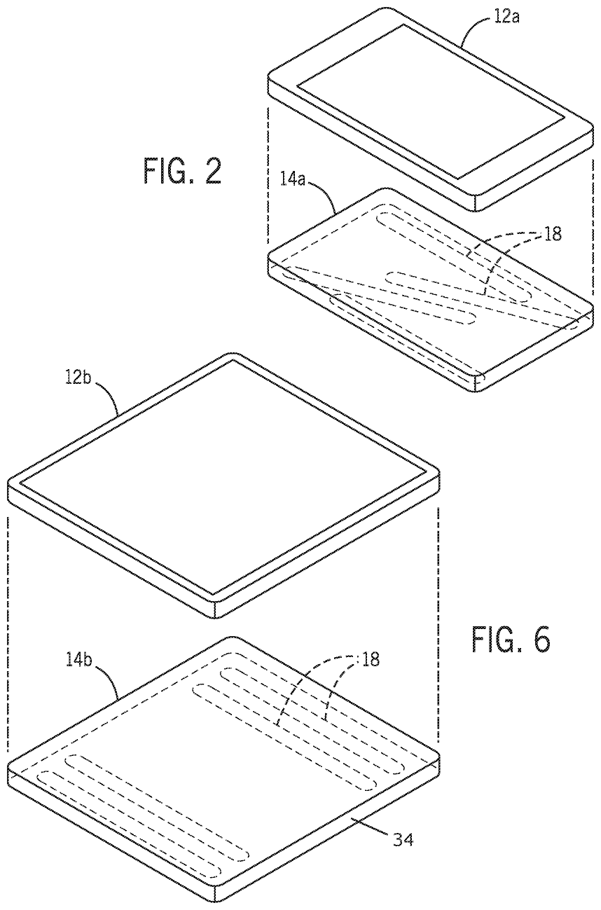

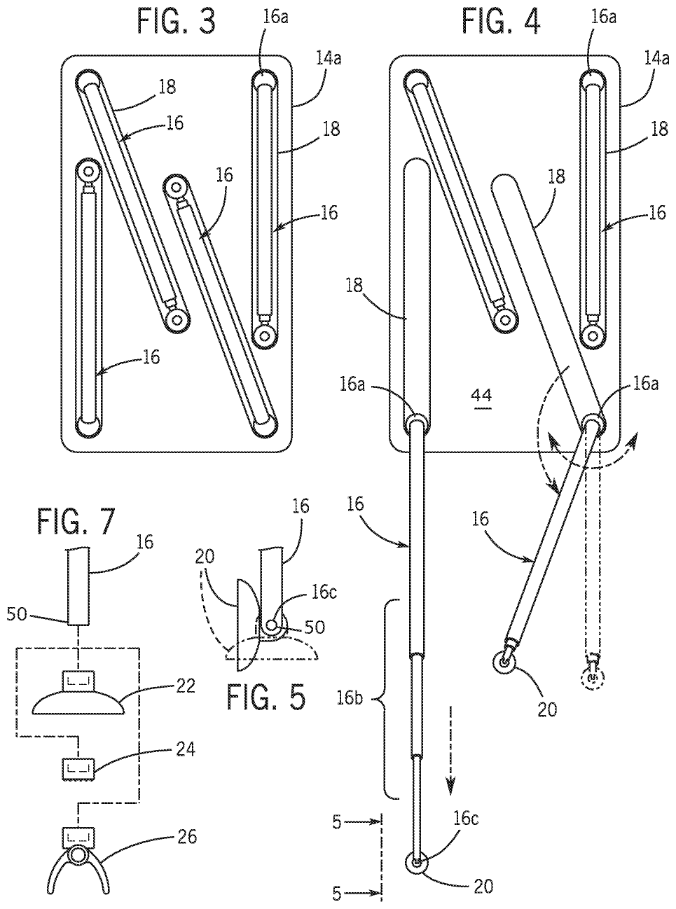

Referring to FIGS. 1 through 7, the present invention may embody one or more systemic cases 14a and 14b, each dimensioned and adapted to secure the peripheral edges and rear side of one or more electronic devices 12a, 12b, etc. The electronic devices 12a, 12b, etc. may include laptops, smart devices such as smart phones and tablets, flat screen televisions, video games, calculators or any portable electronic or computing devices.

Each systemic case 14a or 14b provides peripheral portions 34 and a rear portion 44 for structurally engaging the peripheral edges and rear side, respectively of the associated electronic device 12a, 12b. Each rear portion 44 provides a plurality of elongated recesses 18. One of the two opposing ends of each elongated recess 18 provides a first pivotable connection 16a. The first pivotable connection 16a may be adapted to provide 360-degree rotatability, such as through a universal joint. Each first pivotable connection 16a may be disposed adjacent and/or just inward of a corner of the associated case 14a or 14b, as defined by the peripheral portions 34 thereof.

Attached to each first pivotable connection 16a is a telescopic leg 16. From each hollow telescopic leg 16, one or more telescopic members 16b are dimensioned and adapted to slide between a contracted condition and an expanded condition, as illustrated in FIG. 4. At a distal end 50 of each telescopic member 16b may be a second pivotable connection 16c. The second pivotable connection 16c may pivotably connect a suction member 20 that is enabled to pivot at least 180 degrees relative to a longitudinal axis of the telescopic member 16b, as illustrated in FIG. 5. The second pivotable connection 16c may be adapted to be removable from said distal end 50. The present invention may include a detachable suction member 22, a detachable gripping foot 24, and a detachable gripper 26 that may be selectively engaged with the distal end 50 without the second pivotable connection 16c.

A method of using the present invention may include the following. The systemic case 14a or 14b disclosed above may be provided. Each telescopic leg 16, via the one or more telescopic members 16b, can be extended individually or altogether to selectively provide one of many elevations for the supported electronic device 12a or 12b encased by the systemic case 14a or 14b. The first pivotable connection 16a enables the telescopic legs 16 and thus the systemic case 14a or 14b to be positioned and arranged in various orientations. The detachable and/or folding feet portions (22 and 24 and 26) can be used to provide extra stability so as to prop up the electronic device 12a or 12b in various positions and orientations. As shown in FIG. 1, the present invention includes a two-legged position 10a, utilizing just two telescoping legs 16, and a four-legged positions 10b, whereby users can interact with or view the electronic device 12a or 12b. The suction members 20 and 22, the clip-on feet 24 and the detachable gripper 26 are adapted to engage the distal end 50 to provide further stability for the electronic device 12a or 12b.

The telescopic legs 16 may be placed in the corner of the respective case 14a or 14b, but could be placed in various lengths from the corners to provide more or less stability, and subsequent use can be folded into rear portion 44, which is slightly thicker in the back to make the legs when folded in flush to the rear portion 44 of the case 14a and 14b.

It should be understood, of course, that the foregoing relates to exemplary embodiments of the invention and that modifications may be made without departing from the spirit and scope of the invention as set forth in the following claims.

What is claimed is:

1. A method of ergonomically preventing tech neck for users of an electronic device, comprising the steps of:
providing a systemic case dimensioned to secure a rear portion of the electronic device;
the systemic case having a rear portion with a plurality of elongated recess there along;
a first pivotable connection provided in one end of each elongated recess; and
a telescopic leg pivotable connected to each first pivotable connection so as to be movable between a flush condition circumscribed by the respective elongated recess and an operable condition so that a distal end of the telescopic leg may engage a supporting surface;
encasing the electronic device in the systemic case; and
moving two or more telescopic legs in the operable condition so that the systemic case is elevated above said supporting surface.

2. The method of claim 1, wherein each distal end provides a second pivotable connection connecting to a stabilizing foot.

3. The method of claim 2, wherein each stabilizing foot is a suction member.

4. The method of claim 1, wherein each distal end provides a detachable suction member.

5. The method of claim 1, wherein each distal end provides a detachable gripping foot.

6. The method of claim 1, wherein each distal end provides a detachable gripper.

7. The method of claim 1, further comprising the step of moving an additional two telescopic legs to the operable condition, further changing the orientation of the systemic case in a four-legged orientation.

8. The method of claim 7, further comprising the step of selectively changing the elevation of the systemic case relative to the supporting surface to prevent tech neck.

9. The method of claim 8, further comprising the step of moving the two telescopic legs and the additional two telescopic legs to the flush condition for storage.

10. The method of claim 8, wherein each elongated recess is adjacent to and just inward of a corner of the systemic case.
